(19) United States
(12) Patent Application Publication
(10) Pub. No.: US 2015/0124181 A1
(43) Pub. Date: May 7, 2015

(54) TOUCH DISPLAY DEVICE AND MANUFACTURING METHOD THEREOF

(71) Applicant: Innolux Corporation, Miao-Li County (TW)

(72) Inventors: Mao-Hsing Lin, Miao-Li County (TW); Wei-Wu Pan, Miao-Li County (TW)

(21) Appl. No.: 14/525,236

(22) Filed: Oct. 28, 2014

(30) Foreign Application Priority Data
Nov. 7, 2013 (TW) 102140542

(51) Int. Cl. G06F 1/16; H05K 1/02; H05K 1/09

(52) U.S. Cl. CPC G06F 1/16; H05K 1/09; H05K 1/0298; H05K 2201/0326
USPC 349/12; 29/846

(57) ABSTRACT

A touch display device is provided. The touch display device comprises a display panel and a touch panel disposed on the display panel. The touch panel comprises a touch substrate and a sensing electrode layer. The touch substrate has a first surface, a second surface and a third surface. The first surface is opposite to the third surface and away from the display panel. The second surface is connected to the first surface and the third surface, and has a stress fracture area adjacent to the first surface. The sensing electrode layer is disposed on the third surface.

This application claims the benefit of Taiwan application Serial No. 102140542, filed Nov. 7, 2013, the subject matter of which is incorporated herein by reference.

### BACKGROUND OF THE INVENTION

1. Field of the Invention

The invention relates in general to a display device and a manufacturing method thereof, and more particularly to a touch display device and a manufacturing method thereof.

2. Description of the Related Art

In recent years, a touch display device is provided in response to the popularity of touch-related software and hardware. In the touch display device, a touch panel and a display panel are bonded by using a rectangle-shaped double-sided adhesive and are supported by a backlight frame. The user applies a force on the touch panel of the touch display device to operate the touch display device. Since an ordinary touch panel may have insufficient edge strength, the touch panel may break off and the touch function will be incapacitated if a force is improperly applied on the touch panel. Therefore, how to enhance the edge strength of the touch panel so as to avoid the touch panel breaking has become a prominent task for the industries.

### SUMMARY OF THE INVENTION

The invention is directed to a touch display device and a manufacturing method thereof, which enhances edge strength of a touch panel by way of changing a cutting direction during a cutting process and effectively avoids the touch panel being broken off by a force improperly applied on the touch panel.

According to one embodiment of the present invention, a touch display device is provided. The touch display device comprises a display panel and a touch panel disposed on the display panel. The touch panel comprises a touch substrate and a sensing electrode layer. The touch substrate has a first surface, a second surface and a third surface. The first surface is opposite to the third surface and away from the display panel. The second surface is connected to the first surface and the third surface, and has a stress fracture area adjacent to the first surface. The sensing electrode layer is disposed on the third surface.

According to another embodiment of the present invention, a manufacturing method of a touch display device is provided. The manufacturing method comprises following steps. A touch substrate having a first surface and a third surface opposite to the first surface is provided. A sensing electrode layer is disposed on the third surface to form a plurality of touch panels. A touch substrate having the sensing electrode layer is cut and broken off on the first surface to separate one of the touch panels from the other touch panels. The separated touch panel further has a second surface adjacent to the first surface. The second surface has a stress fracture area adjacent to a cutting edge of the separated touch panel. A display panel is disposed on the third surface of the touch substrate of the separated touch panel to form a touch display device.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a touch display device according to an embodiment of the invention.

FIG. 2A is a 3D schematic diagram of the touch panel of FIG. 1.

FIG. 2B is an enlarged schematic diagram of an area A of the touch panel of FIG. 1.

FIG. 2C is an enlarged schematic diagram of an area A of a touch panel treated with a grinding process according to an embodiment of the invention.

FIGS. 3A˜3G are steps of a flowchart of a manufacturing method of a touch display device according to an embodiment of the invention.

FIG. 4 is a schematic diagram of performing a stress test on a touch panel.

FIG. 5 is a schematic diagram of a touch panel being deformed in the stress test as indicated in FIG. 4 according to an embodiment of the invention.

### DETAILED DESCRIPTION OF THE INVENTION

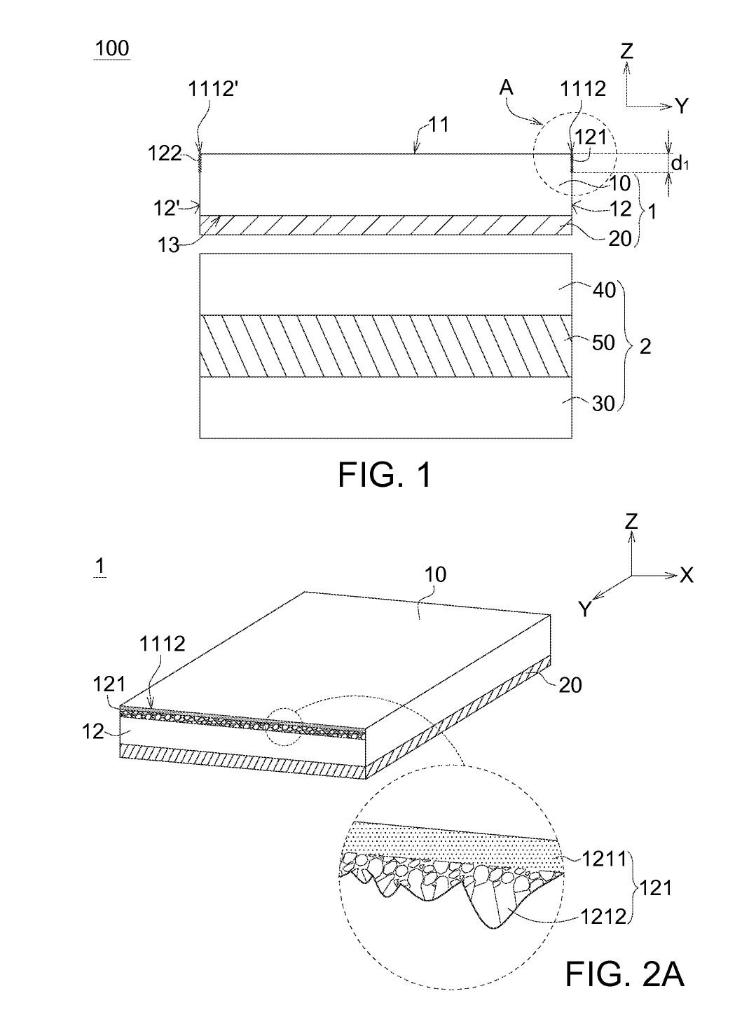

FIG. 1 is a schematic diagram of a touch display device 100 according to an embodiment of the invention. As indicated in FIG. 1, the touch display device 100 comprises a touch panel 1 and a display panel 2. The touch panel 1 is disposed on the display panel 2, and comprises a touch substrate 10 and a sensing electrode layer 20. The touch substrate 10 has a first surface 11, a second surface 12 and a third surface 13. The first surface 11 is opposite to the third surface 13 and away from the display panel 2. The third surface 13 is adjacent to the display panel 2. The sensing electrode layer 20 is disposed on the third surface 13. The second surface 12 is connected to the first surface 11 and the third surface 13, and has a stress fracture area 121 adjacent to the first surface 11. The stress fracture area 121 is formed on the second surface 12 after a cutting process and a breaking process are performed on the first surface 11.

In the present embodiment, the touch panel 1 can be a capacitive touch panel or a resistive touch panel, and the first surface 11 can be a touch pressing surface. That is, the user can press the first surface 11 of the touch substrate 10 with an object such as a finger or a stylus, such that the touch display device 100 generates a corresponding specific function. For example, the user presses one point or multi-points on the first surface 11 or generates a pressing locus on the first surface 11.

In an embodiment, the cutting process may comprise forming a cutter mark on the touch substrate 10 by using a cutting knife. After the cutting process is completed, the vibration of a transfer device enables the touch substrate 10 to be separated along the cutter mark or transferred to a breaking device to be treated with the breaking process. The breaking process may comprise separating the touch substrate 10 according to a position of the cutter mark.

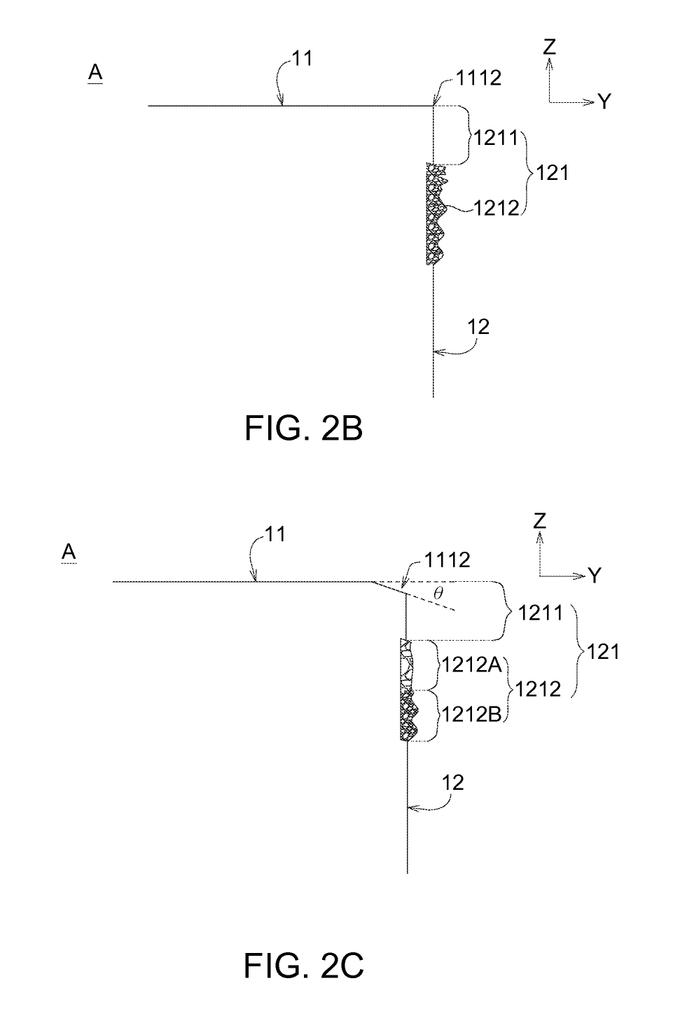

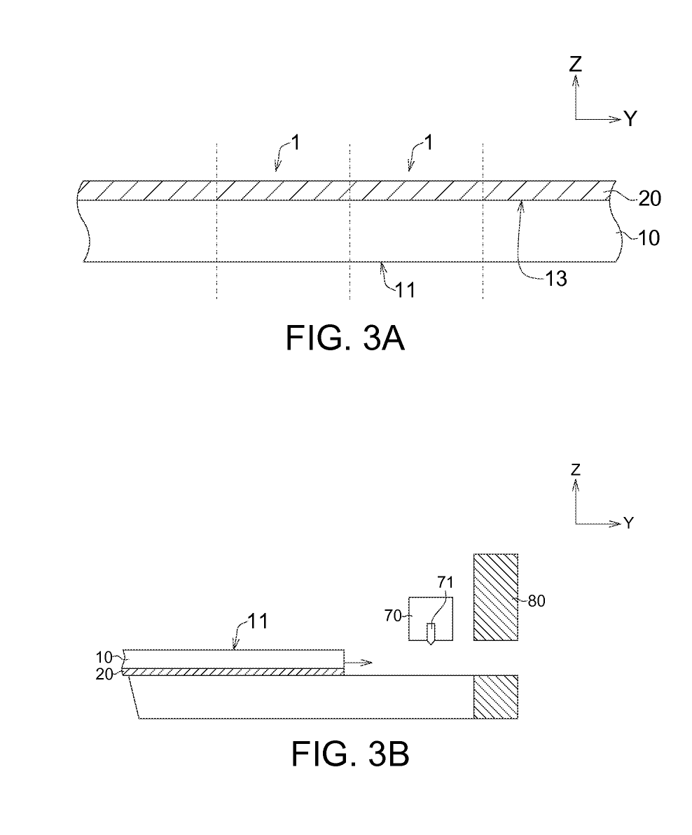

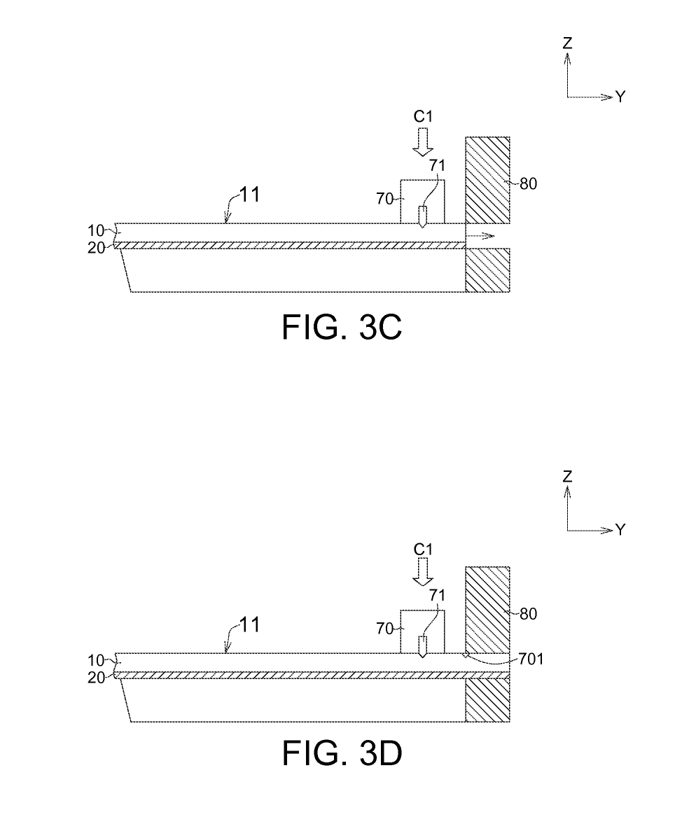

FIG. 2A is a 3D schematic diagram of the touch panel 1 of FIG. 1. FIG. 2B is an enlarged schematic diagram of an area A of the touch panel 1 of FIG. 1. In an embodiment, the touch substrate 10 may have another second surface 12′ adjacent to the first surface 11. The second surface 12′ has a stress fracture area 122 adjacent to the first surface 11. Since the structures of the second surface 12′ and the stress fracture area 122 are similar to the second surface 12 and the stress fracture area 121, only the descriptions of the second surface 12 and the stress fracture area 121 are described below.

As indicated in FIG. 1, the stress fracture area 121 has a width d1 along a direction (that is, a Z direction) substantially perpendicular to the first surface 11. In an embodiment, the width d1 is between 20 μm˜80 μm, but the invention is not limited thereto. Since the stress fracture area 121 is formed by performing a cutting process and a breaking process on the first surface 11, the width d1 is dependent on parameter setting of the manufacturing process.

As shown in FIGS. 1, 2A and 2B, the stress fracture area 121 may have a first area 1211 and a second area 1212. The first area 1211 is, for example, an area of the touch substrate 1 contacting the cutting knife during the cutting process, and connected to the first surface 11. Therefore, the width of the first area 1211 along the direction (that is, the Z direction) substantially perpendicular to the first surface 11 is relevant to a tooth depth of the cutting knife. In an embodiment, the first area 1211 has a width about 7 um or 10 μm along the direction substantially perpendicular to the first surface 11.

The second area 1212, such as a rough area, has cracks. For example, the cracks are formed when a breaking device applies a force on the touch substrate 10 along a cutter mark of the cutting knife. The touch substrate 10 may be transferred to the breaking device through the vibration of a transfer device, or moved to the breaking device. In an embodiment, the cracks may have a plurality of micro-structures having an irregular shape or a shell shape. The second area 1212 has a width between 10 μm˜70 μm along the direction (that is, the Z direction) substantially perpendicular to the first surface 11. Likewise, the width of the second area 1212 along the direction (that is, the Z direction) substantially perpendicular to the first surface 11 and the shape of the cracks may vary with the parameter setting of the manufacturing process and the machine equipment used in the manufacturing process.

In an embodiment, the touch panel can further be treated with a grinding process. FIG. 2C is an enlarged schematic diagram of an area A of a touch panel treated with a grinding process according to an embodiment of the invention. Since the second surface 12 is adjacent to the first surface 11, an intersection 1112 between the first surface 11 and the second surface 12 is treated with the grinding process to form a first sub-area 1212A and a second sub-area 1212B on the second area 1212. The first sub-area 1212A is an area treated with the grinding process. That is, the first sub-area 1212A is an area formed after an intersection 1112 between the first surface 11 and the second surface 12 is treated with the grinding process. Besides, the first sub-area 1212A and the second sub-area 1212B include micro-structures, and the micro-structure of the first sub-area 1212A is different from the micro-structure of the second sub-area 1212B as shown in FIG. 2C.

In the present embodiment, the grinding process can make the intersection 1112 become a chamfer θ of about 20°, but the invention is not limited thereto. The chamfer θ can be between 10˜40° depending on the equipment used in the grinding process. As shown in FIG. 2C, the chamfer θ is a beveled edge connecting the first surface 11 and a portion of the first area 1211. In an embodiment, the second surface 12 can be a round angle of 180° connecting the first surface 11 and the third surface 13. A comparison between FIG. 2C and FIG. 2B shows that since a force is applied on the first sub-area 1212A of the second area 1212 in the grinding process, the surface of the first sub-area 1212A is smoother and has a lower roughness. That is, the roughness on the first area 1211 and the roughness on the first sub-area 1212A of the second area 1212 can both be reduced, and the cracks can be decreased. Meanwhile, the roughness on the surface of the first sub-area 1212A is different from the roughness on the surface of the second sub-area 1212B.

When the user presses the touch panel 1 with an object such as a finger or a stylus, a stress is generated and applied on the touch panel 1. Meanwhile, the first surface 11 receives a compressive stress, and the sensing electrode layer 20 receives a tensile stress. Since the stress fracture area 121 is adjacent to the first surface 11, the stress fracture area 121 also receives a compressive stress.

On the second area 1212, the cracks receiving a tensile stress are more likely to spread than the cracks receiving a compressive stress. That is, more cracks will be formed on the tensile-stress-receiving surface due to the spreading effect of cracks. Once the cracks spreads to a threshold, the touch panel 1 will break off completely. In addition, the cracks may incapacitate the touch function. That is, when the cracks spreads to an area which the user presses or touches with an object such as a finger or a stylus, the touch panel 1 will fail to generate a corresponding specific function.

According to the touch display device 100 of an embodiment of the invention, the stress fracture area with cracks 121 is disposed on a compressive stress surface. Hence, it is effectively avoiding the spreading of the cracks. That is, the touch display device 100 of an embodiment of the invention has better compressive resistance and effectively avoids the touch panel 1 from being broken off and incapacitated when the user improperly applies a force on the touch panel.

In an embodiment, the display panel 2 may comprise a first substrate 30, a second substrate 40 and a dielectric layer 50 as indicated in FIG. 1. The second substrate 40 is disposed on the first substrate 30. The dielectric layer 50 is located between the first substrate 30 and the second substrate 40.

In an embodiment, the display panel 2 can be a liquid crystal display panel, and the dielectric layer 50 of the display panel 2 can be a liquid crystal layer, but the invention is not limited thereto. In another embodiment, the display panel 2 can also be an organic light-emitting diode (OLED) display panel.

In an embodiment, the first substrate 30 can be a color filter substrate, and the second substrate 40 can be a thin-film transistor (TFT) substrate. Likewise, the varieties of the first substrate 30 and the second substrate 40 are not restricted. In some embodiments, the TFT and the color filter can co-exist in the first substrate 30 or the second substrate 40.

Moreover, the sensing electrode layer 20 of an embodiment of the invention can be made of material such as indium tin oxide (ITO) or indium zinc oxide (IZO).

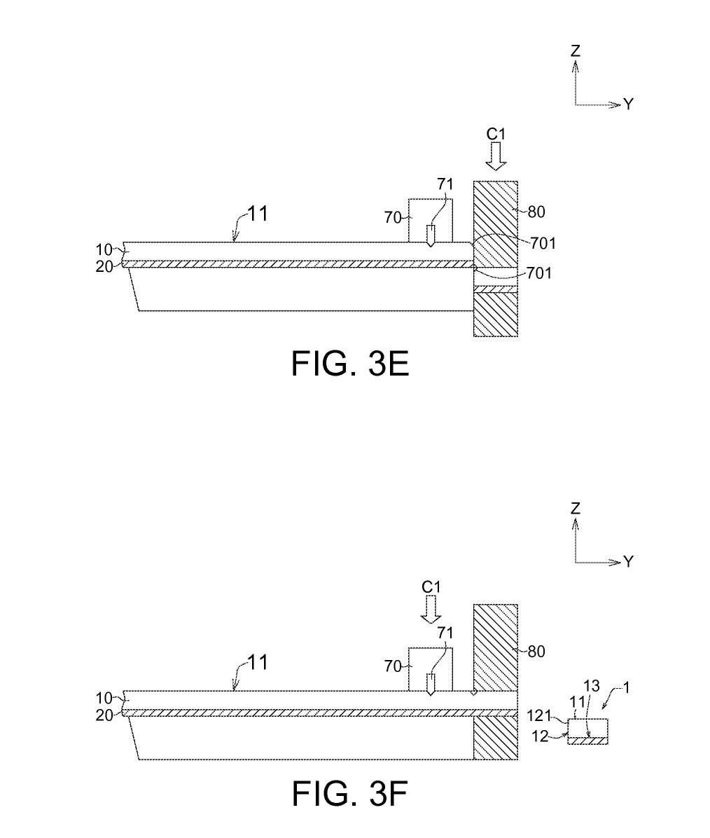

FIGS. 3A˜3G are steps of a flowchart of a manufacturing method of a touch display device 100 according to an embodiment of the invention. The manufacturing method of the touch display device 100 of an embodiment of the invention comprises following steps.

Firstly, as indicated in FIG. 3A, a touch substrate 10 having a first surface 11 and a third surface 13 opposite to the first surface 11 is provided. In the present embodiment, the first surface 11 can be such as a touch pressing surface.

Next, a sensing electrode layer 20 is disposed on the third surface 13 to form a plurality of touch panels 1. In an embodiment, the sensing electrode layer 20 can be disposed on the third surface 13 by using a lithography technology. In another embodiment, the sensing electrode layer 20 can be adhered on the third surface 13 by a transparent adhesive.

Then, a cutting process and a breaking process are performed on the first surface to cut and break off the touch substrate 10 having the sensing electrode layer 20, such that the touch panels 1 are separated from one another. The separated touch panel 1 further has a second surface 12 adjacent to the first surface 11. The second surface 12 has a stress fracture area 121 adjacent to the cutting position of the touch panel 1. Descriptions of the structures of the second surface 12 and the stress fracture area 121 are made with reference to FIGS. 2A and 2B.

Descriptions of the manufacturing method are further disclosed below with accompanying drawings FIGS. 3B˜3F. As indicated in FIG. 3B, the touch substrate 10 having the sensing electrode layer 20 is transferred to a cutting device 70 along a Y direction. The cutting device 70 may comprise at least a cutting knife 71, and can be disposed adjacent to a breaking device 80. Then, as indicated in FIG. 3C, 3D, the cutting device 70 forms a cutter mark 701 on the first surface 11 along a C1 direction (parallel to a Z direction) by using the cutting knife 71, and further transfers the touch substrate 10 having the sensing electrode layer 20 to the breaking device 80. Then, as indicated in FIGS. 3E and 3F, the breaking device 80 breaks off the touch substrate 10 having the sensing electrode layer 20 along the C1 direction (parallel to the Z direction) according to a position of the cutter mark 701 to obtain a separated touch panel 1.

In an embodiment, prior to the step of transferring the touch substrate 10 having the sensing electrode layer 20 to the cutting device 70 along the Y direction, the manufacturing method may further comprise a turning over step for turning over the first surface 11 of the touch substrate 10 to face upward. In the present embodiment, after the touch panel 1 is treated with the cutting process and the breaking process, the touch panel 1 may have another stress fracture area 122 opposite to the stress fracture area 121 (not shown in FIG. 3F).

Then, as indicated in FIG. 3G, a display panel 2 is disposed on the third surface 13 of the touch panel 1 to form the touch display device 100 as indicated in FIG. 1. In an embodiment, the display panel 2 can be adjacent to the sensing electrode layer 20.

In an embodiment, an intersection 1112 between the first surface 11 and the second surface 12 or the intersection 1112′ between the first surface 11 and the second surface 12′ can be treated with a grinding process, such that the second area 1212 comprises a first sub-area 1212A and a second sub-area 12126. The first sub-area 1212A is an area treated with the grinding process. The grinding process makes a partial surface of the stress fracture area 121 or the stress fracture area 122 (such as the surface of the first sub-area 1212A) smoother and at the same time reduces the cracks.

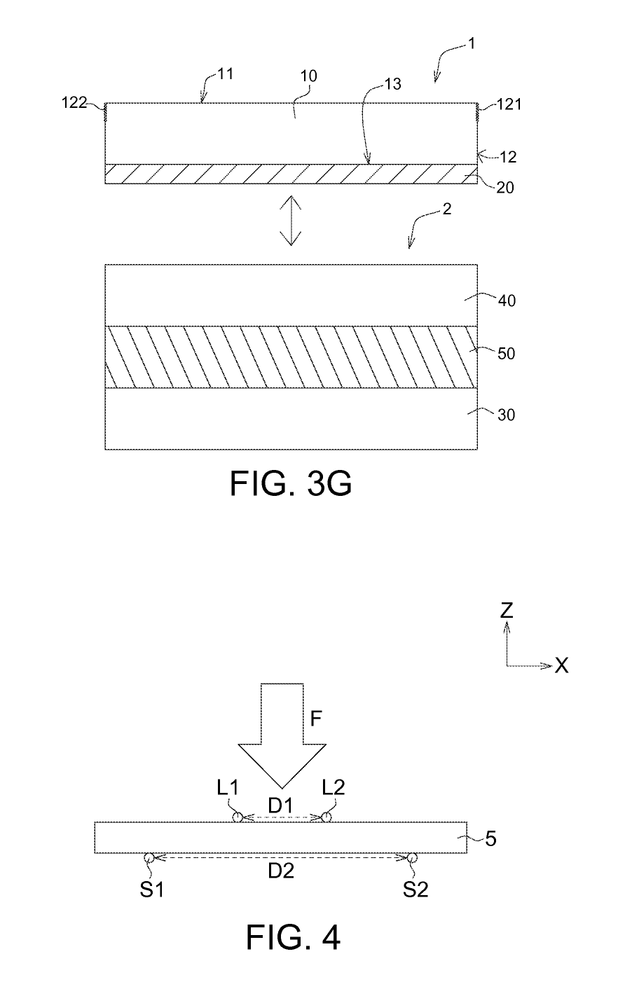

FIG. 4 is a schematic diagram of performing a stress test on a touch panel. In the present embodiment, a 4-point bending test is used as the stress test.

As indicated in FIG. 4, a 4-point bending test is performed on a touch panel 5. The touch panel 5 has a length of 60 mm, a width of 40 mm, and a thickness of 0.5 mm. The touch panel 5 comprises a touch substrate and a sensing electrode layer (not illustrated), and can be such as the touch panel 1 of an embodiment of the invention. Meanwhile, the 4-point bending test can also be performed on the touch panel of a comparison example. The touch panel of the comparison example is different from the touch panel of an embodiment of the invention in that when the cutting process or the breaking process is performed on touch panel of the comparison example, the cutting process is performed on a surface of the touch substrate having the sensing electrode layer.

During the 4-point bending test, a stress is applied on load bearings L1 and L2, and the touch panel 5 is supported by support bearings S1 and S2. One side of the touch panel 5 contacting the load bearing L1 and L2 receives a compressive stress, while the other side of the touch panel 5 contacting the support bearing S1 and S2 receives a tensile stress. When the stress gradually increases to a threshold at which the touch panel 5 will generate failure, the breaking pressure a (MPa) at the time point can be obtained according to the following formulas:

$$σ = \frac{3 \times ( D 2 - D 1 ) \times F}{2 \times b \times {h}^{2}}$$

Wherein,

D1 is a distance (mm) between the load bearings L1 and L2;

D2 is a distance (mm) between the support bearings S1 and S2;

F is a stress (N) when the touch panel 5 generates failure;

b is a width (mm) of the touch panel 5;

h is a thickness (mm) of the touch panel 5.

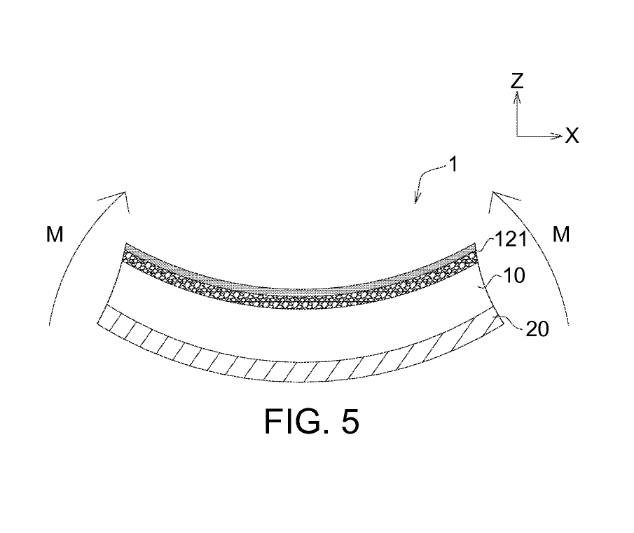

FIG. 5 is a schematic diagram of a touch panel being deformed in the stress test as indicated in FIG. 4 according to an embodiment of the invention. As indicated in FIG. 5, the touch panel 1 generates a deformation along an M direction. That is, on the touch panel 1, the stress fracture area 121 has cracks and is located on a compressive stress receiving surface (located on a top surface of the touch panel 1 and contracting inwardly towards the center), while the sensing electrode layer 20 is located on a tensile stress receiving surface (located on a bottom surface of the touch panel 1 and expanding outwardly).

The cracks receiving a compressive stress are less likely to spread than the cracks receiving a tensile stress. That is, the compressive stress will not generate new cracks. Therefore, the touch panel 1 of an embodiment of the invention has stronger compressive resistance.

In the embodiments and comparison examples disclosed below, tests are performed with different conditions, and experimental results of the tests are analyzed according to the Weibull distribution. Furthermore, a breaking pressure (referred as B10 value) corresponding to a probability of 10% is taken and recorded. In an embodiment of the invention, the cutting process is performed on a surface of the touch substrate away from the sensing electrode layer (on the first surface 11 of FIG. 1). In the comparison example of the invention, the cutting process is performed on a surface of the touch substrate on which the sensing electrode layer is disposed.

Table 1 and Table 2 show the results of a 4-point bending test after a touch panel is cut by using machine A and machine B respectively. The “single-grinded cutting edge” refers to grinding a portion of a touch panel contacting the cutting knife during the cutting process.

Table 1 shows the results of the 4-point bending test performed on a touch panel having been treated with a cutting process and a breaking process by machine A. The conditions of machine A are set as follows: cutting knife: machine with 125 degrees/110 teeth, PENETT, Mitsubishi (MDI);

whetstone of grinding wheel: resin mixed adhesive;

feed rate of grinding: 7,800 mm/min;

rotation speed of grinding: 14,000 rpm.

TABLE 1

| | | Breaking Pressure |
|---|---|---|
| | | (B10 value) |
| Conditions | | (MPa) |
| Embodiments | Cutting the first surface/ | 265.33 |
| | Single-grinded cutting edge | |
| | Cutting the first surface/No grinding | 196.91 |
| Comparison | Cutting the sensing electrode layer/ | 170.54 |
| Examples | Single-grinded cutting edge | |
| | Cutting the sensing electrode layer/ | 129.89 |
| | No grinding | |

Table 2 shows the results of a 4-point bending test performed on a touch panel having been treated with a cutting process and a breaking process by a machine B. The conditions of machine B are set as follows: cutting knife: machine with 125 degrees/110 teeth, PENETT, Mitsubishi (MDI);

whetstone of grinding wheel: metal mixed adhesive;

feed rate of grinding: 6,800 mm/min;

rotation speed of grinding: 12,000 rpm.

TABLE 2

| | | Breaking Pressure |
|---|---|---|
| | | (B10 value) |
| Conditions | | (MPa) |
| Embodiments | Cutting the first surface/ | 211.71 |
| | Single-grinded cutting edge | |
| | Cutting the first surface/no grinding | 228.86 |
| Comparison | Cutting the sensing electrode layer/ | 119.63 |
| Examples | Single-grinded cutting edge | |
| | Cutting the sensing electrode layer/ | 105.92 |
| | No grinding | |

As shown in Table 1 and Table 2, no matter machine A or machine B is used for cutting a touch substrate, the touch panel of an embodiment of the invention (a cutting process and a breaking process are performed on a first surface of the touch panel) significantly bears larger stress fracture than the touch panel of a comparison example (a cutting process and a breaking process are performed on a surface of the touch panel on which a sensing electrode layer is disposed). That is, according to the touch display device and the manufacturing method thereof of the invention, the cutting process is performed on a surface of the touch panel not having a sensing electrode layer, such that the touch panel has better compressive resistance and effectively avoids the touch panel 1 from being broken off and incapacitated when the user improperly applies a force on the touch panel.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A touch display device, comprising:
a display panel; and
a touch panel disposed on the display panel, wherein the touch panel comprises:
a touch substrate having a first surface, a second surface and a third surface, wherein the first surface is opposite to the third surface and away from the display panel, and the second surface is connected to the first surface and the third surface; and
a sensing electrode layer disposed on the third surface;
wherein the second surface has a stress fracture area adjacent to the first surface.

2. The touch display device according to claim 1, wherein the stress fracture area has a width between 20 μm˜80 μm along a direction substantially perpendicular to the first surface.

3. The touch display device according to claim 1, wherein the stress fracture area has a first area and a second area, and the first area is connected to the first surface.

4. The touch display device according to claim 3, wherein the second area has cracks.

5. The touch display device according to claim 4, wherein the second area has a first sub-area and a second sub-area, the first sub-area and the second sub-area comprise micro-structures, and the micro-structure of the first sub-area is different from the micro-structure of the second sub-area.

6. The touch display device according to claim 3, wherein the second area has a width between 10 μm˜70 μm along a direction substantially perpendicular to the first surface.

7. The touch display device according to claim 3, further comprising a chamfer, wherein the chamfer is a beveled edge connecting the first surface and a portion of the first area.

8. The touch display device according to claim 1, wherein the first surface is a touch pressing surface.

9. The touch display device according to claim 1, wherein the sensing electrode layer is made of indium tin oxide or indium zinc oxide.

10. A manufacturing method of a touch display device, comprising:
providing a touch substrate having a first surface and a third surface opposite to the first surface;
disposing a sensing electrode layer on the third surface to form a plurality of touch panels;
cutting and breaking off the touch substrate having the sensing electrode layer by performing a cutting process and a breaking process on the first surface so that one of the touch panels is separated from other touch panels, wherein the separated touch panel further has a second surface adjacent to the first surface, and the second surface has a stress fracture area adjacent to a cutting edge of the separated touch panel; and
disposing a display panel on the third surface of the touch substrate of the separated touch panel to form a touch display device.

11. The manufacturing method according to claim 10, wherein the stress fracture area is adjacent to the first surface of the touch substrate of the separated touch panel.

12. The manufacturing method according to claim 10, wherein the stress fracture area has a width between 20 μm˜80 μm along a direction substantially perpendicular to the first surface.

13. The manufacturing method according to claim 10, wherein the step of cutting and breaking the touch substrate having the sensing electrode layer comprises:
forming a cutter mark on the first surface of the touch substrate by using a cutting knife;
transferring the touch substrate to a breaking device; and
breaking off the touch substrate by the breaking device according to a position of the cutter mark to obtain the separated touch panel.

14. The manufacturing method according to claim 10, wherein the stress fracture area has a first area and a second area, and the first area is an area of the touch substrate contacting a cutting device.

15. The manufacturing method according to claim 14, further comprising:
performing a grinding process on an intersection between the first surface and the second surface to form a first sub-area and a second sub-area on the second area, wherein the first sub-area is an area treated with the grinding process.

16. The manufacturing method according to claim 14, wherein the second area has a width between 10 μm˜70 μm along a direction substantially perpendicular to the first surface.
